(19) United States
(12) Patent Application Publication
(10) Pub. No.: US 2019/0139921 A1
(43) Pub. Date: May 9, 2019

(54) SEMICONDUCTOR DEVICE

(71) Applicant: Samsung Electronics Co., Ltd., Suwon-si (KR)

(72) Inventors: Nam Gyu BAEK, Suwon-si (KR); In Young LEE, Yongin-si (KR); Hyun Soo CHUNG, Hwaseong-si (KR); Ho Geon SONG, Suwon-si (KR)

(21) Appl. No.: 16/030,272

(22) Filed: Jul. 9, 2018

(30) Foreign Application Priority Data
Nov. 9, 2017 (KR) 10-2017-0148571

(51) Int. Cl. H01L 23/00

(52) U.S. Cl. CPC H01L 24/13; H01L 24/05; H01L 2224/02166; H01L 2224/13082; H01L 2224/0401; H01L 2224/13007; H01L 2224/13006; H01L 2224/10126; H01L 2224/13017

(57) ABSTRACT

A semiconductor device includes a substrate, a contact pad arranged in the substrate, a bump arranged on the contact pad to be electrically connected with the contact pad, an insulating film arranged on the substrate to surround a side surface of the bump and to expose at least a portion of the contact pad to the bump, and a photosensitive film which is formed on the insulating film and comprises a polyimide, wherein the photosensitive film comprises a first region surrounding the side surface of the bump and having a first thickness measured in a vertical direction, and a second region arranged on the first region and having a second thickness thickermeasured in the vertical direction, wherein the second region is spaced apart from the bump in a horizontal direction, and wherein the second thickness is greater than a thickness two times thicker than a difference value between the second thickness and the first thickness.

This application claims the benefit of priority under 35 U.S.C. § 119 to Korean Patent Application No. 10-2017-0148571, filed on Nov. 9, 2017, in the Korean Intellectual Property Office, the disclosure of which is incorporated herein in its entirety by reference.

### BACKGROUND

### Technical Field

The present disclosure relates to a semiconductor device.

### Description of the Related Art

In recent years, as semiconductor devices have become lighter, thinner, shorter, and smaller, external terminals for connecting a semiconductor device to an external power source or another semiconductor device are becoming smaller. Stable implementation of such external terminals has a great effect on reliability of a semiconductor package or other semiconductor device. Therefore, various research is being carried out to enhance the reliability of the external terminals at which electric signals between a semiconductor device and an external device are exchanged.

### SUMMARY

One technical object to be solved by the present disclosure is to provide a semiconductor device which has a photosensitive film with a stepped portion arranged on a side surface of a bump, and effectively removes a residue remaining between the bump and the photosensitive film, thereby enhancing reliability.

According to an exemplary embodiment of the present disclosure, there is provided a semiconductor device, comprising: a substrate; a contact pad arranged in the substrate; a bump arranged on the contact pad to be electrically connected with the contact pad; an insulating film arranged on the substrate to surround a side surface of the bump and to expose at least a portion of the contact pad to the bump; and a photosensitive film which is formed on the insulating film and comprises a polyimide, wherein the photosensitive film comprises a first region surrounding the side surface of the bump and having a first thickness measured in a vertical direction, and a second region arranged on the first region and having a second thickness thicker measured in the vertical direction, wherein the second region is spaced apart from the bump in a horizontal direction, and wherein the second thickness is greater than a thickness two times thicker than a difference value between the second thickness and the first thickness.

According to an exemplary embodiment of the present disclosure, there is provided a semiconductor device, comprising: a substrate; a contact pad arranged in the substrate; a lower bump arranged on the contact pad to be electrically connected with the contact pad, and comprising a first portion which is in contact with the contact pad, and a second portion which is arranged on the first portion; an upper bump arranged on the lower bump to be electrically connected with the lower bump, and comprising a material different from a material of the lower bump; and a photosensitive film which is formed on the substrate, and comprises a first region surrounding a side surface of the first portion of the lower bump and having a first thickness measured in a vertical direction, and a second region arranged on the first region and having a second thickness measured in the vertical direction that is thicker than the first thickness, wherein the second thickness is greater than a thickness two times thicker than a difference value between the second thickness and the first thickness, and wherein a side surface of the second region of the photosensitive film faces the second portion of the lower bump and has a sloped profile in which a distance from the second portion of the lower bump in the horizontal direction increases as the side surface of the second region is farther away from the substrate in the vertical direction.

According to an exemplary embodiment of the present disclosure, there is provided a semiconductor device, comprising: a substrate; a contact pad arranged in the substrate; a lower bump arranged on the contact pad to be electrically connected with the contact pad, and comprising a first portion which is in contact with the contact pad, and a second portion which is arranged on the first portion and has a width greater than a width of the first portion; an upper bump arranged on the lower bump to be electrically connected with the lower bump; and a photosensitive film which is formed on the substrate, and comprises a first region surrounding a side surface of the first portion of the lower bump and having a first thickness, and a second region arranged on the first region and having a second thickness greater than the first thickness, the first thickness and the second thickness being measured in a vertical direction, wherein the second thickness is greater than a thickness two times thicker than a difference value between the second thickness and the first thickness, and wherein the width of the second portion of the lower bump is less than a width two times wider than the width of the first portion of the lower bump.

The objectives that are intended to be addressed by the present disclosure are not limited to those mentioned above, and other objectives that are not mentioned above may be clearly understood to those skilled in the art based on the description provided below.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a top view showing a portion of a semiconductor device according to some exemplary embodiments of the present disclosure;

FIG. 2 is a cross-sectional view taken on line A-A of FIG. 1;

FIG. 3 is a cross-sectional view provided to explain a semiconductor device according to some exemplary embodiments of the present disclosure;

FIG. 4 is a cross-sectional view provided to explain a semiconductor device according to some exemplary embodiments of the present disclosure;

FIG. 5 is a cross-sectional view provided to explain a semiconductor device according to some exemplary embodiments of the present disclosure;

FIG. 6 is a cross-sectional view provided to explain a semiconductor device according to some exemplary embodiments of the present disclosure;

FIG. 7 is a cross-sectional view provided to explain a semiconductor device according to some exemplary embodiments of the present disclosure;

FIG. 8 is a cross-sectional view provided to explain a semiconductor device according to some exemplary embodiments of the present disclosure; and

FIG. 9 is a cross-sectional view provided to explain a semiconductor device according to some exemplary embodiments of the present disclosure.

### DETAILED DESCRIPTION

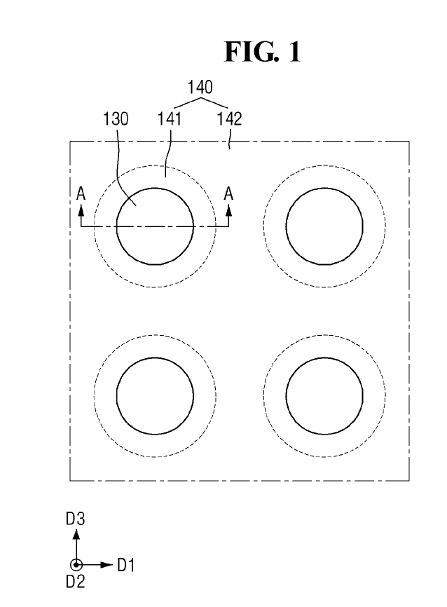

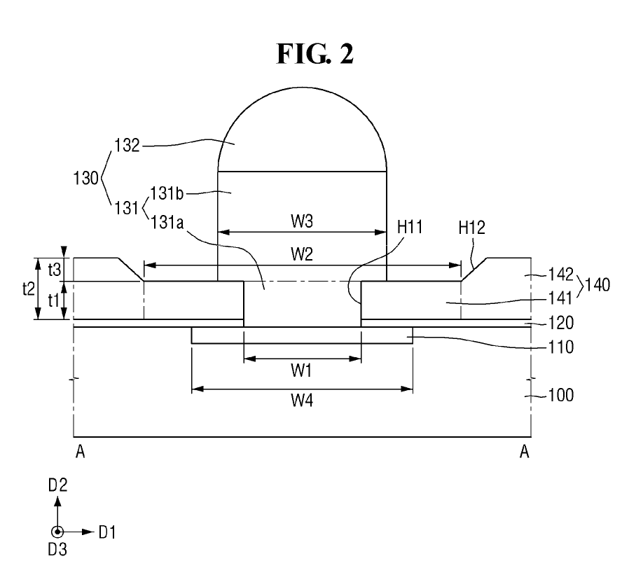

Hereinbelow, a semiconductor device according to some exemplary embodiments will be described with reference to FIG. 1 and FIG. 2.

FIG. 1 is a top view showing a portion of a semiconductor device according to some exemplary embodiments. FIG. 2 is a cross-sectional view taken on line A-A of FIG. 1.

Referring to FIG. 1 and FIG. 2, a semiconductor device according to some exemplary embodiments includes a substrate 100, a contact pad 110, an insulating film 120, a bump 130, and a photosensitive film 140.

The substrate 100 may be a substrate formed on a wafer basis, for example, or may be a substrate formed on a chip basis in which a wafer is divided into a plurality of parts. When the substrate 100 is a substrate formed on a divided chip basis, the substrate 100 may be a memory chip, a logic chip, etc., for example.

When the substrate 100 is a logic chip, the substrate 100 may be designed diversely in consideration of an arithmetic operation to be performed, etc. When the substrate 100 is a memory chip, the memory chip may be a non-volatile memory chip, for example.

Specifically, the memory chip may be a flash memory chip. More specifically, the memory chip may be any one of a NAND flash memory chip or a NOR flash memory chip. However, the present disclosure is not limited thereto. That is, in some exemplary embodiments, the memory chip may include any one of a phase change random access memory (PRAM), a magneto-resistive random access memory (MRAM), or a resistive random access memory (RRAM). In addition, in some exemplary embodiments, when the substrate 100 is a substrate formed on a wafer basis, the substrate 100 may include a logic element or a memory element which performs the same function as described above.

The contact pad 110 may be arranged on one surface of the substrate 100. In some embodiments, the contact pad 110 may be recessed into a top surface of the substrate 100, and the top surface of the contact pad 110 may be flat and may be coplanar with a top surface of the substrate 100. The contact pad 110 may be a bonding pad for electrically connecting an external terminal and a circuit pattern within the substrate 100, for example, but the present disclosure is not limited thereto.

The contact pad 110 may be a re-wired pad or may be a pad which is formed in a through silicon via (TSV), etc. that penetrates through the substrate 100. The contact pad 110 may be formed of metal such as aluminum (Al), etc., for example, but the present disclosure is not limited thereto.

The insulating film 120 may be arranged between the substrate 100 and the photosensitive film 140 to cover the substrate 100 and the contact pad 110. The insulating film 120 may cover a portion of the contact pad 110, while exposing the other portion of the contact pad 110. For example, the insulating film 120 may cover and be in contact with top surfaces of the substrate 100 and the contact pad 110. The insulating film 120 may be arranged to surround a portion of a side surface of the bump 130 arranged on the exposed contact pad 110. For example, a side surface of the insulating film 120 may be in contact with a portion of the side surface of the bump 130.

As shown in FIG. 2, the insulating film 120 does not overlap a portion of the contact pad 110, to allow an electrical connection between the contact pad 110 and the bump 130. The insulating film 120 may include, for example, a nitride film or an oxide film.

The bump 130 may be arranged on the contact pad 110 to be electrically connected with the contact pad 110. The bump 130 may be arranged in the proximity of the center of the contact pad 110. In one embodiment, the bump 130 does not overlap an edge of the contact pad 110. Furthermore, an entire bottom-most surface of the bump 130 may be in contact with the contact pad 110. However, the present disclosure is not limited thereto. As used herein, the term “contact” refers to a connection contact (i.e., touching) unless the context indicates otherwise.

The bump 130 may include a lower bump 131 and an upper bump 132. Specifically, the bump 130 may include the lower bump 131 arranged on the contact pad 110 to be electrically connected with the contact pad 110, and the upper bump 132 arranged on the lower bump 131 to be electrically connected with the lower bump 131. The upper bump 132 and the lower bump 131 may be in contact with one another, and the diameter of the upper bump 132 may be the same as the diameter of the lower bump 131 at the contact area.

The upper bump 132 may be a conductive paste, for example, a solder paste or a metal paste. Specifically, the upper bump 132 may be an alloy of tin and silver (SnAg) or tin (Sn), for example. However, the present disclosure is not limited thereto.

The upper bump 132 may have a hemispherical shape, for example, but the present disclosure is not limited thereto.

The lower bump 131 may include a first portion 131a which is in contact with the contact pad 110, and a second portion 131b which is arranged on the first portion 131a.

The first portion 131a of the lower bump 131 may be arranged on the contact pad 110 exposed by the insulating film 120 to be in contact with the contact pad 110. For example, the insulating film 120 is not arranged between the first portion 131a of the lower bump 131 and the contact pad 110. However, the present disclosure is not limited thereto. In some exemplary embodiments, the insulating film 120 may be arranged on some regions between the first portion 131a of the lower bump 131 and the contact pad 110.

A portion of a side surface of the first portion 131a of the lower bump 131 may be surrounded by the insulating film 120. The other portion of the side surface of the first portion 131a of the lower bump 131 may be surrounded by the photosensitive film 140. For example, the insulating film 120 may extend around a perimeter of a lower portion of the first portion 131a, and the photosensitive film 140 may extend around perimeter of an upper portion of the first portion 131a. The photosensitive film 140 will be described in detail below.

The second portion 131b of the lower bump 131 may be arranged on the first portion 131a of the lower bump 131 and some regions of the photosensitive film 140. In some embodiments, the second portion 131b may be located centrally over the first portion 131a, and may overlap some regions of the photosensitive film 140 by an equal distance on all sides. The first portion 131a of the lower bump 131 may have such a shape as to be recessed toward the inside of the lower bump 131. For example, a side surface of the lower bump may be discontinuous in a third direction D3. Specifically, a width W3 of the second portion 131b of the lower bump 131 may be wider than a width W1 of the first portion 131a of the lower bump 131. The width W3 of the second portion 131b of the lower bump 131 may be narrower than a width two times wider than the width W1 of the first portion 131a of the lower bump 131. That is, the width W3 of the second portion 131b of the lower bump 131 may be wider than the width W1 of the first portion 131a of the lower bump 131, and may be narrower than the width two times wider than the width W1 of the first portion 131a of the lower bump 131. The widths in FIG. 2 are illustrated as being in the first direction D1, but may be in the second direction D2, in some embodiments. The first direction D1 is perpendicular to the second direction D2, both of which are horizontal directions, and the third direction D3 is vertical direction that is perpendicular to both the first direction D1 and the second direction D2.

The surface contact area between the upper bump 132 and the lower bump 131 may correspond to the width W3 of the second portion 131b of the lower bump 131. For example, when the bump 130 has a spherical or circular shape, when viewed from a top-down view, the surface contact area between the upper bump 132 and the lower bump 131 may be equal to π(½*W3)². The surface contact area between the lower bump 131 and the contact pad 110 may correspond to the width W1 of the first portion 131a of the lower bump 131. For example, when the bump 130 has a spherical or circular shape, when viewed from a top-down view, the surface contact area between the lower bump 131 and the contact pad 110 may be equal to π(½*W1)².

Accordingly, the electric connection between the first portion 131a of the lower bump 131 and the contact pad 110 can be efficiently maintained.

The width W3 of the second portion 131b of the lower bump 131 may be narrower than a width W4 of the contact pad 110. However, the present disclosure is not limited thereto.

In some exemplary embodiments, the width W3 of the second portion 131b of the lower bump 131 may be equal to the width W4 of the contact pad 110. In addition, in some exemplary embodiments, the width W3 of the second portion 131b of the lower bump 131 may be wider than the width W4 of the contact pad 110.

Although FIG. 1 and FIG. 2 depict that the second portion 131b of the lower bump 131 has a cylindrical shape, when viewed from a side view, the present disclosure is not limited thereto. That is, in some exemplary embodiments, a side surface of the second portion 131b of the lower bump 131 may have a convex shape when viewed from a side view.

The lower bump 131 may include a material different from a material of the upper bump 132. The lower bump 131 may be formed of various kinds of metals such as nickel (Ni), copper (Cu), palladium (Pd), platinum (Pt), gold (Au), or a combination thereof.

The photosensitive film 140 may be arranged on the insulating film 120 to surround the side surface of the lower bump 131.

The photosensitive film 140 may include a first region 141 arranged to surround the side surface of the first portion 131a of the lower bump 131, and a second region 142 arranged to surround the first region 141.

The first region 141 of the photosensitive film 140 may be in contact with the side surface of the first portion 131a of the lower bump 131. However, the present disclosure is not limited thereto. That is, in some exemplary embodiments, the first region 141 of the photosensitive film 140 may be arranged to be spaced apart from the side surface of the first portion 131a of the lower bump 131.

The photosensitive film 140 may have a structure having a stepped portion. Specifically, a first thickness t1 of the first region 141 of the photosensitive film 140 measured in the third direction D3 from an upper surface of the insulating film 120 to an upper surface of the first region 141 may be thinner than a second thickness t2 of the second region 142 of the photosensitive film 140 measured in the third direction D3 from the upper surface of the insulating film 120 to an upper surface of the second region 142. The portion of the surface that extends from the upper surface of the first region 141 to the upper surface of the second region 142 may be at an oblique angle relative to the top surface of the first region 141.

The structure of the photosensitive film 140 having the stepped portion may be formed by using a phase shift mask, for example. However, the present disclosure is not limited thereto. For example, in some exemplary embodiments, the structure of the photosensitive film 140 having the stepped portion may be formed by using a traditional mask process.

The second thickness t2 of the second region 142 of the photosensitive film 140 may be thicker than a thickness two times thicker than a difference value t3 between the second thickness t2 of the second region 142 of the photosensitive film 140 and the first thickness t1 of the first region 141 of the photosensitive film 140 (i.e., t2>2*(t3), where t3=(t2−t1)).

For example, the first thickness t1 of the first region 141 of the photosensitive film 140 may be thicker than the difference value t3 between the second thickness t2 of the second region 142 of the photosensitive film 140 and the first thickness t1 of the first region 141 of the photosensitive film 140 (i.e., t1>t3, where t3=(t2−t1)).

The first region 141 of the photosensitive film 140 may include a first opening H11 to expose the contact pad 110, and the second region 142 of the photosensitive film 140 may include a second opening H12 to expose the contact pad 110 and an upper surface of the first region 141 of the photosensitive film 140. The first portion 131a of the lower bump 131 may be arranged inside the first opening H11.

A width W2 of the second opening H12 may be wider than the width W1 of the first opening H11. In addition, the width W2 of the second opening H12 may be wider than the width W4 of the contact pad 110. However, the present disclosure is not limited thereto. In some exemplary embodiments, the width W2 of the second opening H12 may be equal to the width W4 of the contact pad 110. In other exemplary embodiments, the width W2 of the second opening H12 may be narrower than the width W4 of the contact pad 110.

A side surface of the first region 141 of the photosensitive film 140 may have a profile in which the width of the first opening H11 is constant in the third direction D3. However, the present disclosure is not limited thereto. For example, the width of the first opening H11 may increase in the third direction D3, or the width of the first opening H11 may decrease in the third direction D3.

A side surface of the second region 142 of the photosensitive film 140 may have a sloped profile. Specifically, the side surface of the second region 142 of the photosensitive film 140 exposed by the second opening H12 may have a sloped profile in which the width of the second opening H12 increases as the side surface of the second region 142 is farther away from the substrate 100. More specifically, the side surface of the second region 142 of the photosensitive film 140, which faces the second portion 131b of the lower bump 131, may have a sloped profile in which a distance from the second portion 131b of the lower bump 131 increases as the side surface of the second region 142 is farther away from the substrate 100.

The photosensitive film 140 may include any one of photosensitive polyimide (PSPI), polyimide (Pi), and photosensitive polyhydroxystyrene, for example, but the present disclosure is not limited thereto. In some embodiments, the photosensitive film 140 may be a continuous material, e.g., a continuously-formed PSPI, a continuously-formed polyimide, a continuously-formed photosensitive polyhydroxystyrene, etc.

In the semiconductor device according to some exemplary embodiments, the photosensitive film 140 having the stepped portion is arranged around the side surface of the bump 130, such that a residue remaining between the bump 130 and the photosensitive film 140 can be effectively removed and thus reliability of the semiconductor device can be enhanced.

In this case, the semiconductor device according to some exemplary embodiments has a limit to the relationship between the first thickness t1 of the first region 141 of the photosensitive film 140 and the second thickness t2 of the second region 142 of the photosensitive film 140 as described above, such that a residue remaining between the second portion 131b of the lower bump 131 and the second region 142 of the photosensitive film 140 can be effectively removed. For example, to enable effective removal of residue between the second portion 131b of the lower bump 131 and the second region 142 of the photosensitive film 140, the ratio of the second thickness t2 to the first thickness t1 remains within certain parameters. In some embodiments, the ratio of the second thickness t2 to the first thickness t1 may be greater than 2:1 (i.e., t1>0.5*(t2)). In such embodiments, the second region 142 of the photosensitive film 140 may be spaced apart in the first direction D1 from the lower bump 131 by a distance that is greater than or equal to one-half the difference between the width W2 and the width W3 (i.e., ½*(W2−W3)).

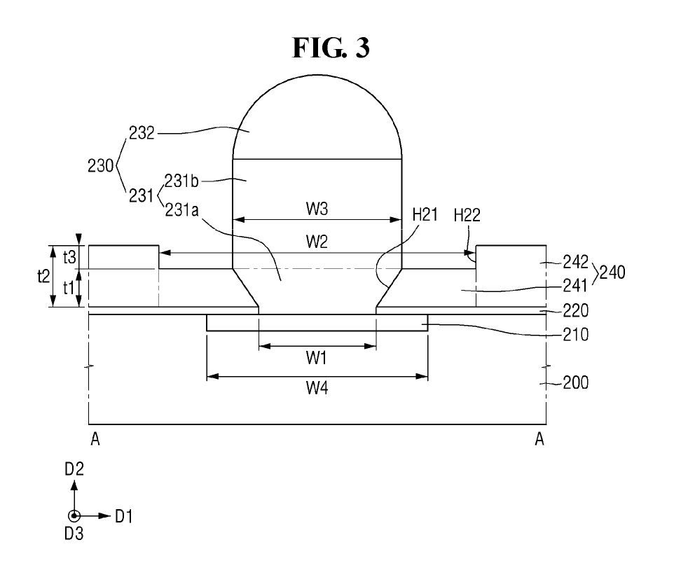

Hereinbelow, a semiconductor device according to some exemplary embodiments will be described with reference to FIG. 3. The difference from the semiconductor device illustrated in FIG. 2 will be highlighted.

FIG. 3 is a cross-sectional view provided to explain a semiconductor device according to some exemplary embodiments.

Referring to FIG. 3, a semiconductor device according to some exemplary embodiments includes a substrate 200, a contact pad 210, an insulating film 220, a bump 230, and a photosensitive film 240. The bump 230 may include upper bump 232 and lower bump 231, and the lower bump 231 may include first portion 231a and second portion 231b. The photosensitive film 240 may include first region 241 and second region 242.

The substrate 200, the contact pad 210, the insulating film 220, and an upper bump 232 may have structures similar to those of the substrate 100, the contact pad 110, the insulating film 120, and the upper bump 132 shown in FIG. 2, respectively.

In the semiconductor device shown in FIG. 3, a side surface of a second region 242 of the photosensitive film 240 may have a profile in which a width of a second opening H22 is constant in the third direction D3, and a side surface of a first region 241 of the photosensitive film 240 may have a sloped profile.

Specifically, the side surface of the second region 242 of the photosensitive film 240 may have a profile in which a distance (e.g., in the first direction D1) between the side surface of the second region 242 and the second portion 231b of a lower bump 231 is constant.

The side surface of the first region 241 of the photosensitive film 240 exposed by a first opening H21 may have a sloped profile in which a width of the first opening H21 increases as the side surface of the first region 241 is farther away from the substrate 200 (e.g., in the third direction D3).

Specifically, a side surface of a first portion 231a of the lower bump 231 in contact with the first region 241 of the photosensitive film 240 may have a sloped profile in which a width of the first portion 231a of the lower bump increases as the side surface of the first portion 231a is farther away from the substrate 200 (e.g., in the third direction D3). For example, the width in the third direction D3 of the first portion 231a may increase from width W1 to width W3 in the portion where the first portion 231a is in contact with the first region 241.

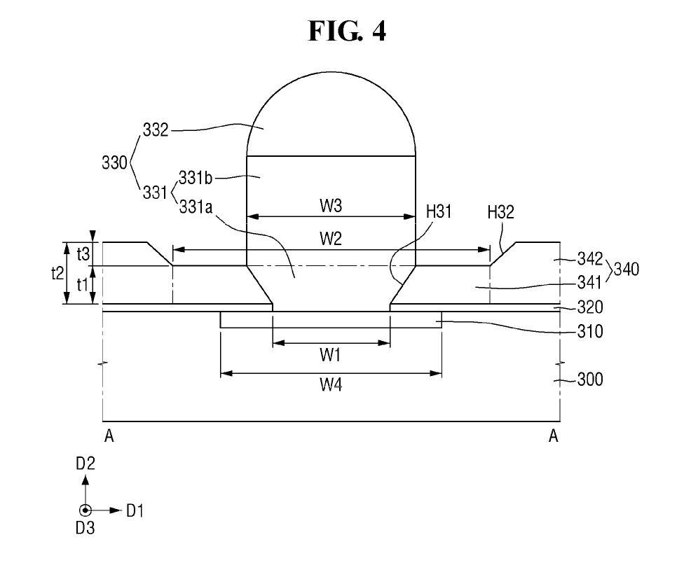

Hereinbelow, a semiconductor device according to some exemplary embodiments will be described with reference to FIG. 4. The difference from the semiconductor device illustrated in FIG. 2 will be highlighted.

FIG. 4 is a cross-sectional view provided to explain a semiconductor device according to some exemplary embodiments.

Referring to FIG. 4, a semiconductor device according to some exemplary embodiments includes a substrate 300, a contact pad 310, an insulating film 320, a bump 330, and a photosensitive film 340. The bump 330 may include upper bump 332 and lower bump 331, and the lower bump 331 may include first portion 331a and second portion 331b. The photosensitive film 340 may include first region 341 and second region 342.

The substrate 300, the contact pad 310, the insulating film 320, a second portion 331b of a lower bump 331, and an upper bump 332 may have structures similar to those of the substrate 100, the contact pad 110, the insulating film 120, the second portion 131b of the lower bump 131, and the upper bump 132 shown in FIG. 2, respectively.

In the semiconductor device shown in FIG. 4, a side surface of a second region 342 of the photosensitive film 340 may have a sloped profile, and a side surface of a first region 341 of the photosensitive film 340 may also have a sloped profile.

Specifically, the side surface of the first region 341 of the photosensitive film 340 exposed by a first opening H31 may have a sloped profile in which a width of the first opening H31 increases as the side surface of the first region 341 is farther away from the substrate 300 (e.g., in the third direction D3).

A side surface of a first portion 331a of the lower bump 331, which is in contact with the first region 341 of the photosensitive film 340, may have a sloped profile in which a width of the first portion 331a of the lower bump 331 increases as the side surface of the first portion 331a is farther away from the substrate 300 (e.g., in the third direction D3). For example, the width in the third direction D3 of the first portion 331a may increase from width W1 to width W3 in the portion where the first portion 331a is in contact with the first region 341.

In addition, the side surface of the second region 342 of the photosensitive film 340 exposed by a second opening H32 may have a sloped profile in which a width of the second opening H32 increases as the side surface of the second region 342 is farther away from the substrate 300 (e.g., in the third direction D3).

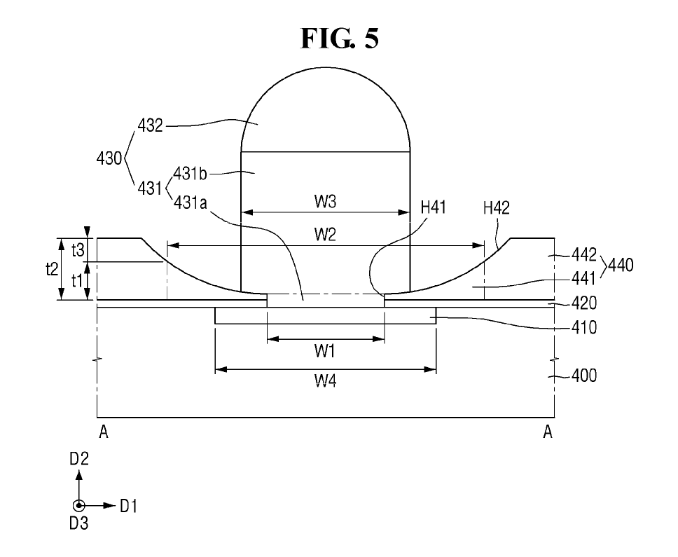

Hereinbelow, a semiconductor device according to some exemplary embodiments will be described with reference to FIG. 5. The difference from the semiconductor device illustrated in FIG. 2 will be highlighted.

FIG. 5 is a cross-sectional view provided to explain a semiconductor device according to some exemplary embodiments.

Referring to FIG. 5, a semiconductor device according to some exemplary embodiments includes a substrate 400, a contact pad 410, an insulating film 420, a bump 430, and a photosensitive film 440. The bump 430 may include upper bump 432 and lower bump 431, and the lower bump 431 may include first portion 431a and second portion 431b. The photosensitive film 440 may include first region 441 and second region 442.

The substrate 400, the contact pad 410, the insulating film 420, and an upper bump 432 may have structures similar to those of the substrate 100, the contact pad 110, the insulating film 120, and the upper bump 132 shown in FIG. 2, respectively.

The semiconductor device shown in FIG. 5 may have a sloped profile in which a side surface of a second region 442 of the photosensitive film 440 and an upper surface of a first region 441 of the photosensitive film 440 are continuous. For example, when viewed in a side view, the side surface of the second region 442 and the upper surface of the first region 441 may have a concave shape.

Specifically, the upper surface of the first region 441 of the photosensitive film 440 exposed by a first opening H41 may have a sloped profile in which a width of the first opening H41 increases as the upper surface of the first region 441 is farther away from the substrate 400 (e.g., in the third direction D3). A first portion 431a of a lower bump 431 which is in contact with a side surface of the first region 441 of the photosensitive film 440 may have a constant width (e.g., width W1). In some embodiments, side surfaces of the first portion 431a may be perpendicular to a top surface of the contact pad 410.

A lower surface of a second portion 431b of the lower bump 431 which is in contact with the upper surface of the first region 441 of the photosensitive film 440 may have a sloped profile in which a width of the second portion 431b of the lower bump 431 increases as the lower surface of the second portion 431b is farther away from the substrate 400 (e.g., in the third direction D3). For example, the width in the third direction D3 of the second portion 431b may increase from width W1 to width W3 in the portion where the lower surface of the second portion 431b is in contact with the first region 441.

In addition, the side surface of the second region 442 of the photosensitive film 440 exposed by a second opening H42 may have a sloped profile in which a width of the second opening H42 increases as the side surface of the second region 442 is farther away from the substrate 400 (e.g., in the third direction D3).

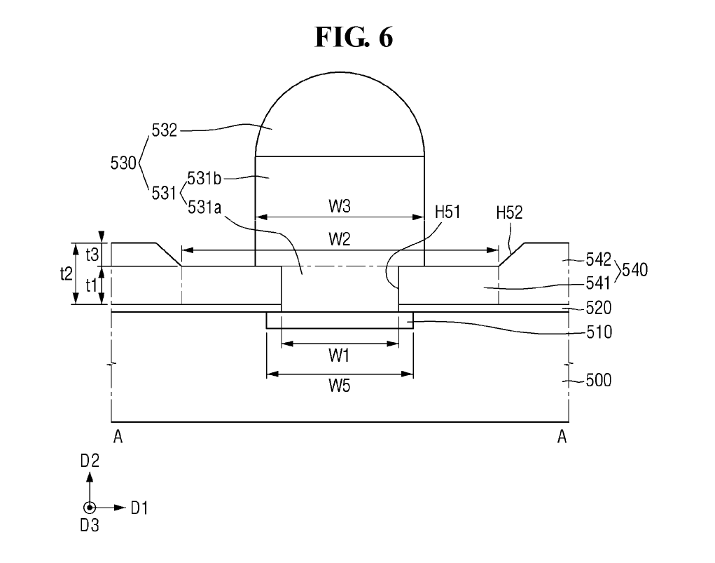

Hereinbelow, a semiconductor device according to some exemplary embodiments will be described with reference to FIG. 6. The difference from the semiconductor device illustrated in FIG. 2 will be highlighted.

FIG. 6 is a cross-sectional view provided to explain a semiconductor device according to some exemplary embodiments.

Referring to FIG. 6, a semiconductor device according to some exemplary embodiments includes a substrate 500, a contact pad 510, an insulating film 520, a bump 530, and a photosensitive film 540. The bump 530 may include upper bump 532 and lower bump 531, and the lower bump 531 may include first portion 531a and second portion 531b. The photosensitive film 540 may include first region 541 and second region 542.

The substrate 500, the insulating film 520, a first portion 531a of a lower bump 531, a second portion 531b of the lower bump 531, an upper bump 532, a first region 541 of the photosensitive film 540, a second region 542 of the photosensitive film 540, a first opening H51, and a second opening H52 may have structures similar to those of the substrate 100, the insulating film 120, the first portion 131a of the lower bump 131, the second portion 131b of the lower bump 131, the upper bump 132, the first region 141 of the photosensitive film 140, the second region 142 of the photosensitive film 140, the first opening H11, and the second opening H12 shown in FIG. 2, respectively.

In the semiconductor device shown in FIG. 6, a width W5 of the contact pad 510 may be wider than a width W1 of the first portion 531a of the lower bump 531. In addition, the width W5 of the contact pad 510 may be narrower than a width W3 of the second portion 531b of the lower bump 531.

For example, a portion of an edge of the second portion 531b of the lower bump 531 may not overlap the contact pad 510. In some embodiments, when viewed in a top-down view, a perimeter area of the second portion 531b of the lower bump 531 may extend beyond an area of the contact pad 510.

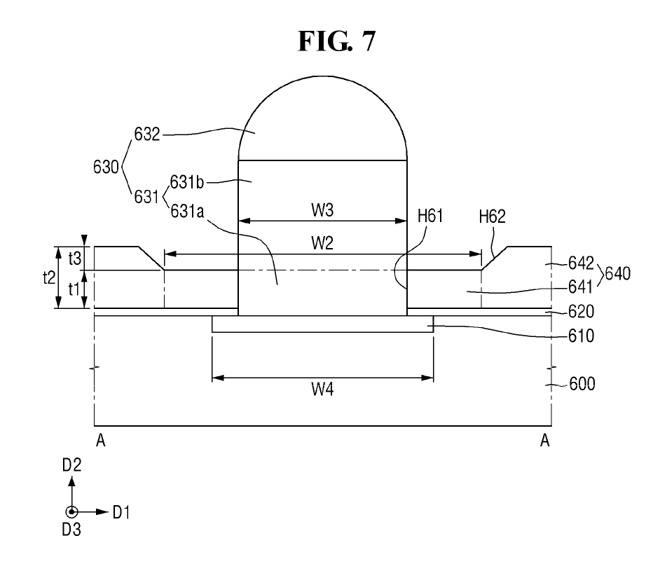

Hereinbelow, a semiconductor device according to some exemplary embodiments will be described with reference to FIG. 7. The difference from the semiconductor device illustrated in FIG. 2 will be highlighted.

FIG. 7 is a cross-sectional view provided to explain a semiconductor device according to some exemplary embodiments.

Referring to FIG. 7, a semiconductor device according to some exemplary embodiments includes a substrate 600, a contact pad 610, an insulating film 620, a bump 630, and a photosensitive film 640. The bump 630 may include upper bump 632 and lower bump 631, and the lower bump 631 may include first portion 631a and second portion 631b. The photosensitive film 640 may include first region 641 and second region 642.

The substrate 600, the contact pad 610, a second portion 631b of a lower bump 631, an upper bump 632, a second region 642 of the photosensitive film 640, and a second opening H62 may have structures similar to those of the substrate 100, the contact pad 110, the second portion 131b of the lower bump 131, the upper bump 132, the second region 142 of the photosensitive film 140, and the second opening H12 shown in FIG. 2, respectively.

In the semiconductor device shown in FIG. 7, a first portion 631a of the lower bump 631 is not recessed toward the inside of the lower bump 631. For example, side surface of the first portion 631a and the second portion 631b of the lower bump 631 may be continuous in the third direction D3, and may be perpendicular to the top surface of the contact pad 610.

Specifically, the first portion 631a of the lower bump 631 may have a same width W3 as a width of the second portion 631b of the lower bump 631. For example, a width of a first opening H61 in which the first portion 631a of the lower bump 631 is arranged may be the same as the width W3 of the second portion 631b of the lower bump 631.

The insulating film 620 and a first region 641 of the photosensitive film 640 may be arranged to surround the first portion 631a of the lower bump 631. For example, the insulating film 620 and the first region 641 may extend along and be in contact with side surfaces of the first portion 631a of the lower bump 631.

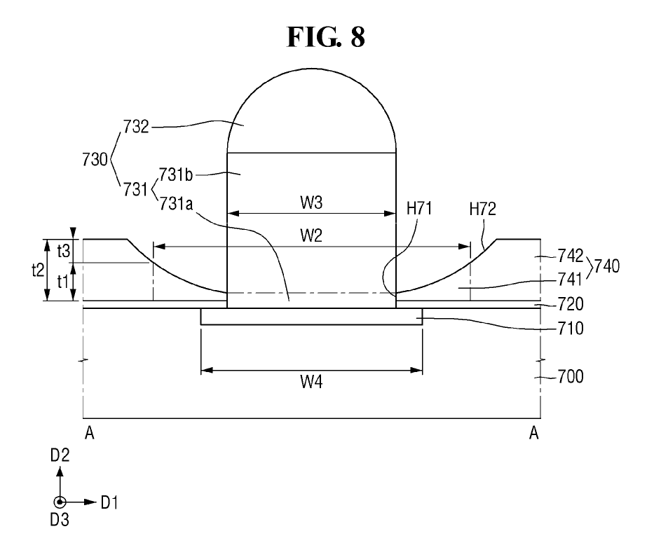

Hereinbelow, a semiconductor device according to some exemplary embodiments will be described with reference to FIG. 8. The difference from the semiconductor device illustrated in FIG. 7 will be highlighted.

FIG. 8 is a cross-sectional view provided to explain a semiconductor device according to some exemplary embodiments.

Referring to FIG. 8, a semiconductor device according to some exemplary embodiments includes a substrate 700, a contact pad 710, an insulating film 720, a bump 730, and a photosensitive film 740. The bump 730 may include upper bump 732 and lower bump 731, and the lower bump 731 may include first portion 731a and second portion 731b. The photosensitive film 740 may include first region 741 and second region 742.

The substrate 700, the contact pad 710, the insulating film 720, a first portion 731a of a lower bump 731, a second portion 731b of the lower bump 731, and an upper bump 732 may have structures similar to those of the substrate 600, the contact pad 610, the insulating film 620, the first portion 631a of the lower bump 631, the second portion 631b of the lower bump 631, and the upper bump 632 shown in FIG. 7, respectively.

The semiconductor device shown in FIG. 8 may have a sloped profile in which a side surface of a second region 742 of the photosensitive film 740 and an upper surface of a first region 741 of the photosensitive film 740 are continuous. For example, when viewed in a side view, the side surface of the second region 742 and the upper surface of the first region 741 may have a concave shape.

Specifically, the upper surface of the first region 741 of the photosensitive film 740 exposed by a first opening H71 may have a sloped profile in which a width of the first opening H71 increases as the supper surface of the first region 741 is farther away from the substrate 700 (e.g., in the third direction D3). A first portion 731a of the lower bump 731 which is in contact with a side surface of the first region 741 of the photosensitive film 740 may have a constant width (e.g., width W3). In some embodiments, side surfaces of the first portion 731a may be perpendicular to a top surface of the contact pad 710.

In addition, the side surface of the second region 742 of the photosensitive film 740 exposed by a second opening H72 may have a sloped profile in which a width of the second opening H72 increases as the side surface of the second region 742 is farther away from the substrate 700 (e.g., in the third direction D3).

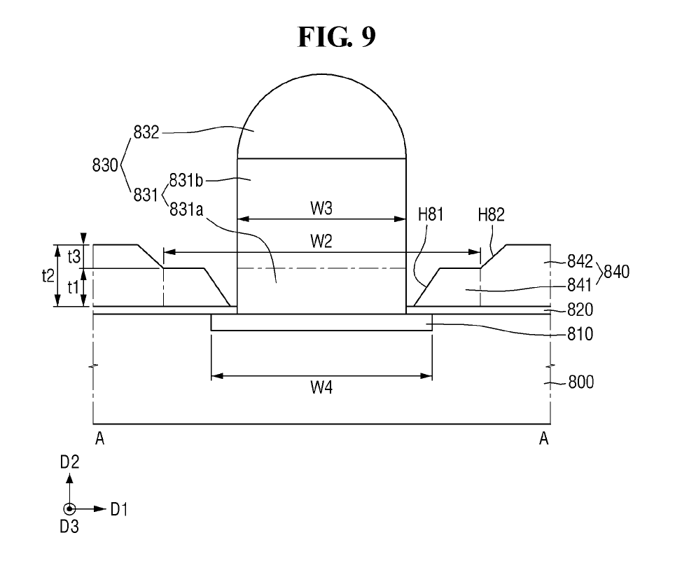

Hereinbelow, a semiconductor device according to some exemplary embodiments will be described with reference to FIG. 9. The difference from the semiconductor device illustrated in FIG. 7 will be highlighted.

FIG. 9 is a cross-sectional view provided to explain a semiconductor device according to some exemplary embodiments.

Referring to FIG. 9, a semiconductor device according to some exemplary embodiments includes a substrate 800, a contact pad 810, an insulating film 820, a bump 830, and a photosensitive film 840. The bump 830 may include upper bump 832 and lower bump 831, and the lower bump 831 may include first portion 831a and second portion 831b. The photosensitive film 840 may include first region 841 and second region 842.

The substrate 800, the contact pad 810, the insulating film 820, a first portion 831a of a lower bump 831, a second portion 831b of the lower bump 831, an upper bump 832, a second region 842 of the photosensitive film 840, and a second opening H82 may have structures similar to those of the substrate 600, the contact pad 610, the insulating film 620, the first portion 631a of the lower bump 631, the second portion 631b of the lower bump 631, the upper bump 632, the second region 642 of the photosensitive film 640, and the second opening H62 shown in FIG. 7, respectively.

In the semiconductor device shown in FIG. 9, a first region 841 of the photosensitive film 840 may be arranged to be spaced apart from the first portion 831a of the lower bump 831. The insulating film 820 may be arranged to be in contact with the first portion 831a of the lower bump 831. A portion of the insulating film 820 adjacent to the first portion 831a of the lower bump 831 may be exposed between the first portion 831a of the lower bump 831 and the first region 841 of the photosensitive film 840.

A side surface of the first region 841 of the photosensitive film 840 may have a sloped profile. Specifically, the side surface of the first region 841 of the photosensitive film 840, which faces the first portion 831a of the lower bump 831, may have a sloped profile in which a width of a first opening H81 increases as the side surface of the first region 841 is farther away from the substrate 800 (e.g., in the third direction D3).

In the embodiment of FIG. 9, a portion of a top surface of the insulating film 820 may be exposed. For example, a bottom corner of the sloped side surface of the first region 841 may be spaced apart from the sidewall of the first portion 831a of the lower bump 831 in the horizontal direction, such that the portion of the top surface of the insulating film 820 is not covered by either the first portion 831a of the lower bump 831 or the first region 841.

Exemplary embodiments according to the present disclosure were explained hereinabove with reference to the drawings attached, but it should be understood that the present disclosure is not limited to the aforementioned exemplary embodiments, but may be fabricated in various different forms, and may be implemented by a person skilled in the art in other specific forms without altering the technical concept characteristics of the present disclosure. Accordingly, it will be understood that the exemplary embodiments described above are only illustrative, and should not be construed as limiting.

What is claimed is:

1. A semiconductor device, comprising:
a substrate;
a contact pad arranged in the substrate;
a bump arranged on the contact pad to be electrically connected with the contact pad;
an insulating film arranged on the substrate to surround a side surface of the bump and to expose at least a portion of the contact pad to the bump; and
a photosensitive film which is formed on the insulating film and comprises a polyimide, wherein the photosensitive film comprises a first region surrounding the side surface of the bump and having a first thickness measured in a vertical direction, and a second region arranged on the first region and having a second thickness thicker measured in the vertical direction,
wherein the second region is spaced apart from the bump in a horizontal direction, and
wherein the second thickness is greater than a thickness two times thicker than a difference value between the second thickness and the first thickness.

2. The semiconductor device of claim 1, wherein the first region of the photosensitive film comprises a first opening to allow the contact pad to be exposed therethrough,
wherein the second region of the photosensitive film comprises a second opening to allow an upper surface of the first region of the photosensitive film and the contact pad to be exposed therethrough, and
wherein a width of the second opening is greater than a width of the first opening.

3. The semiconductor device of claim 2, wherein a side surface of the second opening faces the bump and has a sloped profile in which the width of the second opening increases as the side surface of the second opening is farther away from the substrate in a vertical direction.

4. The semiconductor device of claim 2, wherein a side surface of the first opening faces the bump and has a sloped profile in which the width of the first opening increases as the side surface of the first opening is farther away from the substrate in a vertical direction.

5. The semiconductor device of claim 2, wherein the width of the second opening is greater than a width of the contact pad.

6. The semiconductor device of claim 1, wherein the bump comprises:
a lower bump comprising a first portion which is in contact with the contact pad, and a second portion which is arranged on the first portion and has a width greater than a width of the first portion; and
an upper bump arranged on the lower bump to be electrically connected with the lower bump,
wherein the first region of the photosensitive film is in contact with a side surface of the first portion of the lower bump.

7. The semiconductor device of claim 6, wherein the width of the second portion of the lower bump is less than a width two times wider than the width of the first portion of the lower bump.

8. The semiconductor device of claim 6, wherein a width of the contact pad is greater than the width of the first portion of the lower bump, and is less than the width of the second portion of the lower bump.

9. The semiconductor device of claim 1, wherein the first region of the photosensitive film is arranged to be spaced apart from the bump.

10. A semiconductor device, comprising:
a substrate;
a contact pad arranged in the substrate;
a lower bump arranged on the contact pad to be electrically connected with the contact pad, and comprising a first portion which is in contact with the contact pad, and a second portion which is arranged on the first portion;
an upper bump arranged on the lower bump to be electrically connected with the lower bump, and comprising a material different from a material of the lower bump; and
a photosensitive film which is formed on the substrate, and comprises a first region surrounding a side surface of the first portion of the lower bump and having a first thickness measured in a vertical direction, and a second region arranged on the first region and having a second thickness measured in the vertical direction that is thicker than the first thickness,
wherein the second thickness is greater than a thickness two times thicker than a difference value between the second thickness and the first thickness, and
wherein a side surface of the second region of the photosensitive film faces the second portion of the lower bump and has a sloped profile in which a distance from the second portion of the lower bump in the horizontal direction increases as the side surface of the second region is farther away from the substrate in the vertical direction.

11. The semiconductor device of claim 10, wherein a width of the first portion of the lower bump is less than a width of the second portion of the lower bump.

12. The semiconductor device of claim 10, wherein a width of the second portion of the lower bump is less than a width two times wider than a width of the first portion of the lower bump.

13. The semiconductor device of claim 10, wherein the side surface of the first portion of the lower bump has a sloped profile in which a width of the first portion of the lower bump in the horizontal direction increases as the side surface of the first portion is farther away from the substrate in the vertical direction.

14. The semiconductor device of claim 10, wherein a width of the first portion of the lower bump is the same as a width of the second portion of the lower bump.

15. The semiconductor device according to claim 10, wherein the photosensitive film comprises a polyimide.

16. A semiconductor device, comprising:
a substrate;
a contact pad arranged in the substrate;
a lower bump arranged on the contact pad to be electrically connected with the contact pad, and comprising a first portion which is in contact with the contact pad, and a second portion which is arranged on the first portion and has a width greater than a width of the first portion;
an upper bump arranged on the lower bump to be electrically connected with the lower bump; and
a photosensitive film which is formed on the substrate, and comprises a first region surrounding a side surface of the first portion of the lower bump and having a first thickness, and a second region arranged on the first region and having a second thickness greater than the first thickness, the first thickness and the second thickness being measured in a vertical direction,
wherein the second thickness is greater than a thickness two times thicker than a difference value between the second thickness and the first thickness, and
wherein the width of the second portion of the lower bump is less than a width two times wider than the width of the first portion of the lower bump.

17. The semiconductor device of claim 16, wherein a side surface of the second region of the photosensitive film faces the second portion of the lower bump and has a sloped profile in which a distance from the second portion of the lower bump in the horizontal direction increases as the side surface of the second region is farther away from the substrate in the vertical direction.

18. The semiconductor device of claim 16, wherein a width of the contact pad is greater than the width of the first portion of the lower bump, and is less than the width of the second portion of the lower bump.

19. The semiconductor device of claim 16, wherein the upper bump and the lower bump comprise material different from each other.

20. The semiconductor device of claim 16, further comprising an insulating film surrounding the side surface of the first portion of the lower bump between the substrate and the photosensitive film, and exposing the contact pad to the lower bump.
